(19) United States
(12) Patent Application Publication
(10) Pub. No.: US 2007/0066089 A1
(43) Pub. Date: Mar. 22, 2007

(54) Micro security digital card

(75) Inventor: Chin Chun Liu, Miaoli Hsien (TW)

Correspondence Address: BACON & THOMAS, PLLC, 625 SLATERS LANE, FOURTH FLOOR, ALEXANDRIA, VA, 22314, US

(73) Assignee: Sun-Light Electronic Technologies Inc., Miaoli Hsien (TW)

(21) Appl. No.: 11/330,240

(22) Filed: Jan. 12, 2006

(30) Foreign Application Priority Data
Sep. 19, 2005 (TW) 94216107

(51) Int. Cl. H05K 1/00

(52) U.S. Cl. 439/55

(57) ABSTRACT

The present invention provides a micro security digital card including: a first shell having a receiving space; a second shell with a periphery thereof forming an embedding part; an integrated circuit with one side thereof provided with a plurality of contacts; and an intermediate element disposed between the second shell and the integrated circuit. The receiving space of the first shell sequentially receives the second shell, the intermediate element and the integrated circuit. The embedding part of the second shell is embedded into the first shell such that the second shell tightly combines with the first shell. The integrated circuit tightly combines with the second shell by means of the intermediate element.

### BACKGROUND OF THE INVENTION

1. Field of the Invention

The present invention relates to a micro security digital card, especially to a micro security digital card having a simple structure, being able to be assembled quickly, having increasing production yield and reduced cost.

2. Description of the Related Art

With developments of technology and material for electronic ICs, the application thereof is increasingly popular. There are many types of products mainly based on the electronic ICs, these products not only have powerful function, but also tend toward a light, thin, short and small form. These products include, for example, electronic dictionary, digital still camera, digital video recorder and various digital products, etc.

Micro security digital card, hereinafter briefly referred to Micro SD, is a new current storage media. It has a lighter, thinner, shorter and smaller size than current popular MMC Card, SD Card and XD Card. Further, it has many properties such as small size, high compatibility, low cost, large storage capacity, rapid transmission and high secrecy. As such, it can be used in a mobile phone, PDA, computer and various multi-media for storing or transmitting data. Because Micro SD is the most miniaturized memory storage card, it has become the most popular product in the current market.

Referring to FIG. 13A and FIG. 13B, perspective views of a conventional Micro SD card are shown. The process for manufacturing the conventional Micro SD card is a package process in which the contact is firstly packaged to become a rectangular form. The packaged rectangular form is mechanically cut into a desired shape and assembled as a Micro SD card. However, this process is not only complicated, costly, and low production yield, but also has sharp edges in appearance, i.e. without bevels, resulting that the conventional Micro SD can not be frequently replaced in a reading device. As such, the conventional Micro SD still has some drawbacks and needs to be improved.

### SUMMARY OF THE INVENTION

It is the object of the present invention to provide a micro security digital card, in which a first shell combines with a second shell by insert molding to become a housing, and an integrated circuit combines with the housing by means of an intermediate element to form the present micro security digital card.

For the above purpose, a micro security digital card includes: a first shell having a receiving space; a second shell with a periphery thereof forming an embedding part; an integrated circuit with one side thereof provided with a plurality of contacts; and an intermediate element disposed between the second shell and the integrated circuit. The receiving space of the first shell sequentially receives the second shell, the intermediate element and the integrated circuit. The embedding part of the second shell is embedded into the first shell such that the second shell tightly combines with the first shell. The integrated circuit tightly combines with the second shell by means of the intermediate element.

Preferably, the first shell is made of plastic material.

Preferably, the second shell is made of metal material.

Preferably, the intermediate element is a thermoplastic plate, the thermoplastic plate can be heated and pressurized to combine the second shell and the integrated circuit.

Preferably, the embedding part of the second shell includes a first embedding part and a second embedding part.

Preferably, the second embedding part is O-shaped.

Preferably, the second embedding part is L-shaped.

Preferably, the second embedding part is U-shaped.

Preferably, the sides of the first embedding part form bevels.

Preferably, one side of the first embedding part forms a recess.

### BRIEF DESCRIPTION OF THE DRAWINGS

FIG. 1 is a perspective view of a first shell of the present invention.

FIG. 2 is a perspective view of a second shell of the present invention.

FIG. 3A is a front view of the second shell; FIG. 3B is a bottom view of the second shell and FIG. 3C is an enlarged view of part A in FIG. 3A.

FIG. 4 is a perspective view of an intermediate element of the present invention.

FIG. 5 is a perspective view of an integrated circuit of the present invention.

FIG. 6A and FIG. 6B are perspective views of the combination of the first shell and the second shell of the present invention.

FIG. 7A is a top view of the combination of the first shell and the second shell; FIG. 7B is a cross-sectional view of FIG. 7A taken along line A-A and FIG. 7C is an enlarged view of part B in FIG. 7B.

FIG. 8A and FIG. 8B are perspective views of the micro security digital card of the present invention.

FIG. 9A is a top view of the micro security digital card of the present invention; FIG. 9B is a cross-sectional view of FIG. 9A taken along line B-B and FIG. 9C is an enlarged view of part C in FIG. 9B.

FIG. 10 is a cross-sectional view of an O-shaped second embedding part.

FIG. 11 is a cross-sectional view of an L-shaped second embedding part.

FIG. 12 is a cross-sectional view of a U-shaped second embedding part.

FIG. 13A is a perspective view of a conventional Micro SD card; and FIG. 13B is another perspective view of a conventional Micro SD card.

### DETAILED DESCRIPTION OF THE PREFERRED EMBODIMENTS

While the invention will be thoroughly described with reference to drawings containing preferred embodiments of the invention, however, prior to description, it is to be understood that those who are skilled in this art can carry out various modifications to the present invention and also achieve the effectiveness of the present invention. Hence, it is to be understood that the following description of the present invention should be accorded with the broadest interpretation to those who are skilled in this art, and the invention is not limited thereto.

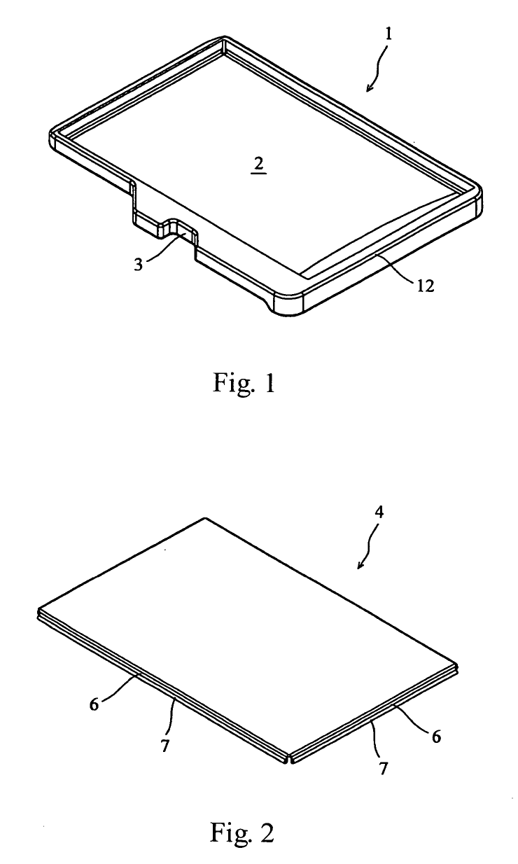

Referring to FIG. 1, a perspective view of a first shell of the present micro security digital card is shown. The first shell 1 has a first receiving space 2. The sides of the first shell 1 form bevels 12 and a recess 3 is formed on an outer side of the first shell 1. The first shell 1 is made of plastic material.

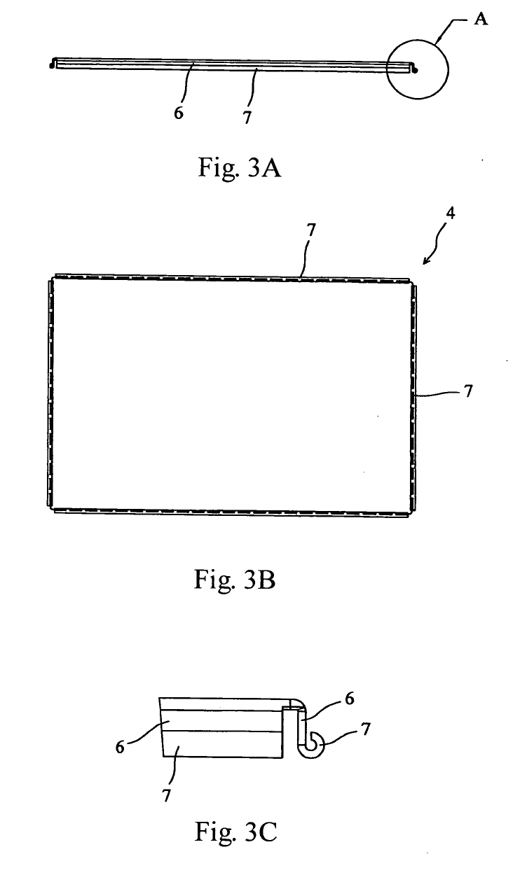

Referring to FIG. 2, FIG. 3A, FIG. 3B and FIG. 3C, a perspective view, a front view, a bottom view and an enlarged view of part A in FIG. 3A are respectively shown. In a preferred embodiment of the present invention, a plurality of first embedding parts 6 vertically extend from the sides of the second shell 4, and a second embedding part 7 extends from one end of the respective first embedding part 6. The second embedding part 7 is O-shaped. The second shell 4 is made of metal material.

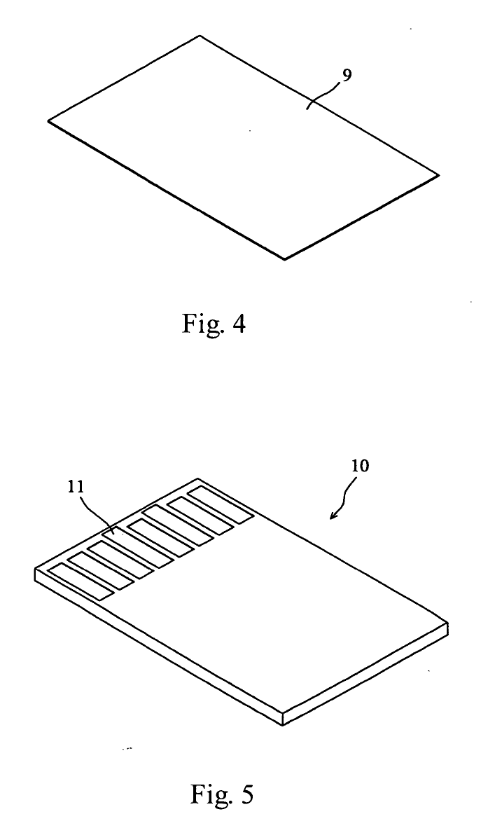

Referring to FIG. 4, a perspective view of an intermediate element is shown. In a preferred embodiment of the present invention, the intermediate element is a thermoplastic plate 9 and has a thin-film structure.

Referring to FIG. 5, a perspective view of an integrated circuit is shown. One side of the integrated circuit 10 is provided with a plurality of parallel-arranged contacts 11.

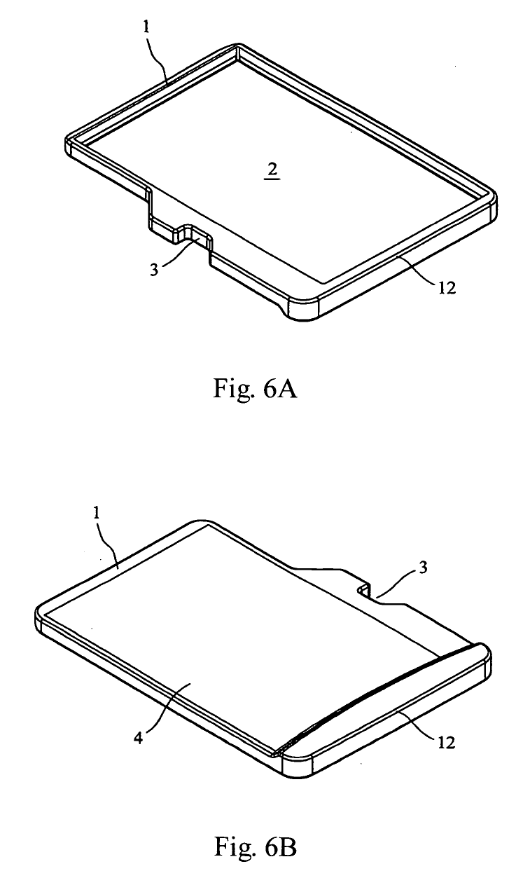

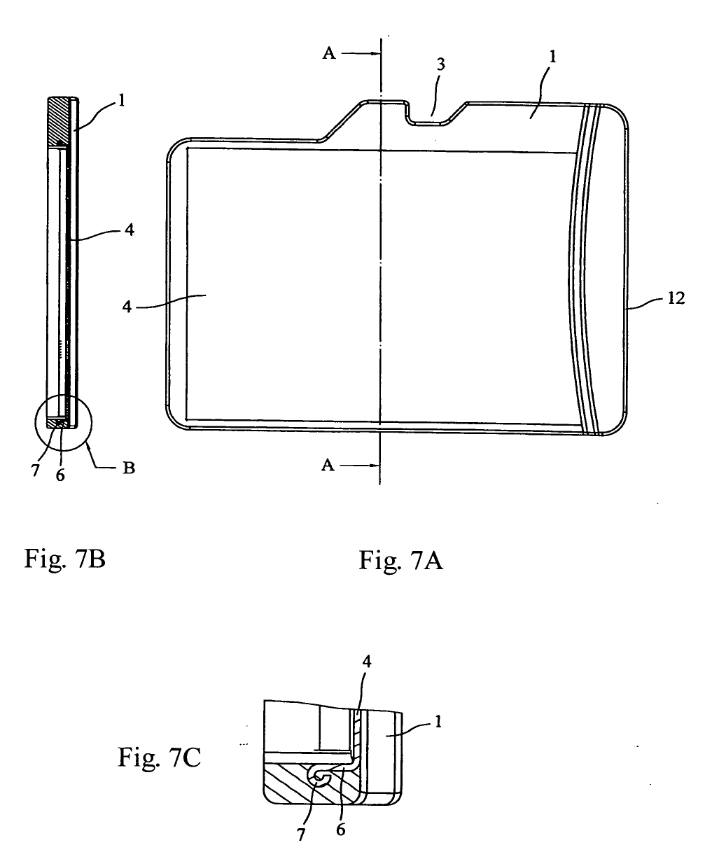

Referring to FIG. 6A and FIG. 6B, two perspective views of the combination of the first shell 1 and the second shell 4 are shown. Referring to FIG. 7A, FIG. 7B and FIG. 7C, a top view of the combination of the first shell 1 and the second shell 4, a cross-sectional view of FIG. 7A taken along line A-A and an enlarged view of part B in FIG. 7B are respectively shown. The first shell 1 and the second shell 4 are insert molded to become a housing. The second shell 4 is received in the receiving space 2 of the first shell 1 by the embedding of the first embedding part 6 and the second embedding part 7.

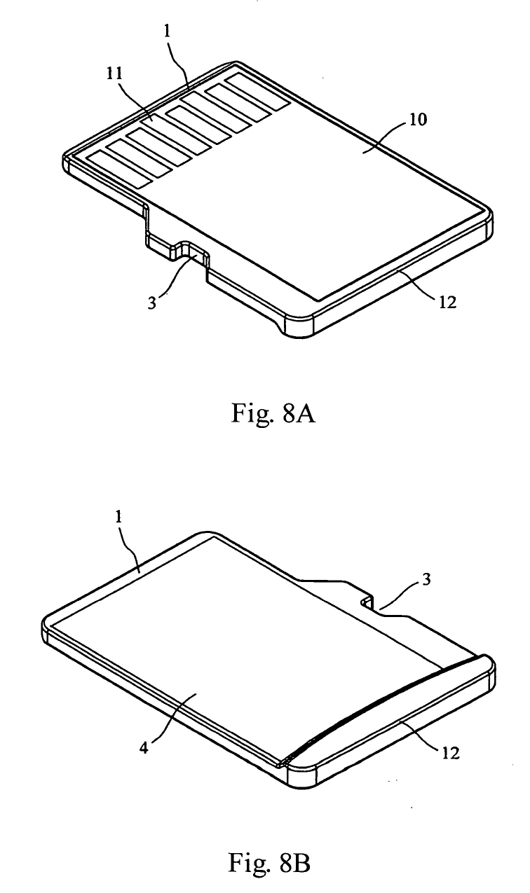

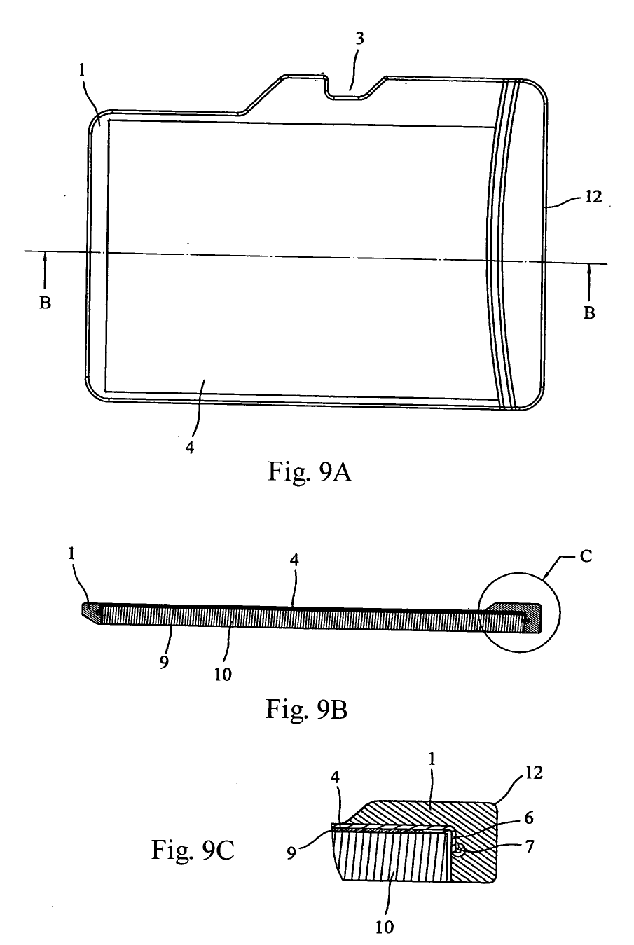

Referring to FIG. 8A and FIG. 8B, two perspective views of the micro security digital card of the present invention are shown. The integrated circuit 10 tightly combines with the second shell 4 by heating and pressurizing the thermoplastic plate 9 (with reference to FIG. 9B and FIG. 9C), and the integrated circuit 10 is received in the receiving space 2 of the first shell 1.

Referring to FIG. 9A, FIG. 9B and FIG. 9C, a top view of the micro security digital card of the present invention, a cross-sectional view of FIG. 9A taken along line B-B and an enlarged view of part C in FIG. 9B are respectively shown. The micro security digital card of the present invention includes: a first shell 1 having a receiving space 2; a second shell 4 with a periphery thereof forming a plurality of embedding parts, and each of which including a first embedding part 6 and a second embedding part 7; an integrated circuit 10 with one side thereof provided with a plurality of parallel-arranged contacts 11; and a thermoplastic plate 9 disposed between the second shell 4 and the integrated circuit 10. The receiving space 2 of the first shell 1 sequentially receives the second shell 4, the thermoplastic plate 9 and the integrated circuit 10. The first embedding part 6 and the second embedding part 7 are embedded in the first shell 1 by insert molding such that the second shell 4 tightly combines with the first shell 1. The integrated circuit 10 tightly combines with the second shell 4 by the thermoplastic plate 9.

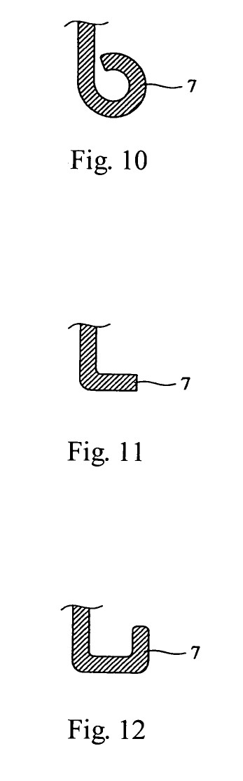

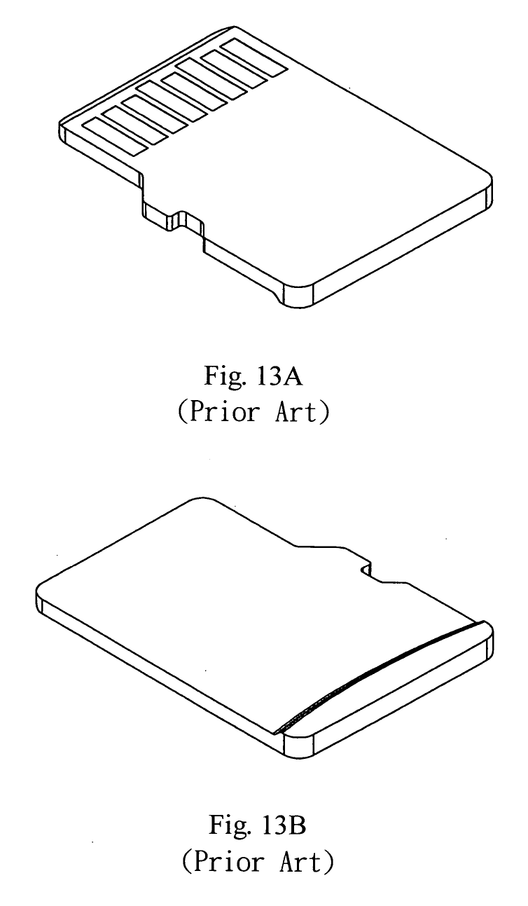

Referring to FIG. 10, FIG. 11 and FIG. 12, a cross-sectional view of an O-shaped second embedding part, a cross-sectional view of an L-shaped second embedding part and a cross-sectional view of a U-shaped second embedding part are respectively shown. In a preferred embodiment of the present invention, the second embedding part 7 is implemented as an O-shaped second embedding part 7.

The present invention provides advantages such as the present manufacturing method is a continuous process with improved production yield and reduced cost, the micro security digital card has a simple structure and can be assembled quickly, the micro security digital card produced by the present method also can endure impact and is not easily stripped off. In addition, the micro security digital card is convenient for use and has an aesthetically pleasing appearance as a whole.

Although the present invention has been described in considerable detail with reference to certain preferred embodiments thereof, those skilled in the art can clearly understand that all kinds of alterations and changes can be made within the spirit of the appended claims. And the present invention is also not limited to the implementations of these embodiments exemplified in the specification. For example, the shape of the second embedding part may also be L-shaped (with reference to FIG. 11) or U-shaped (with reference to FIG. 12). In the embodiment, the second embedding part in combination with the first shell, the second embedding part is implemented in the O-shaped, L-shaped, U-shaped and any combination thereof.

What is claimed is:

1. A micro security digital card, comprising:
a first shell having a receiving space;
a second shell with a periphery thereof forming at least one embedding part;
an integrated circuit with one side thereof provided with a plurality of contacts; and
an intermediate element disposed between said second shell and said integrated circuit;
wherein said second shell, said intermediate element and said integrated circuit are sequentially received in the receiving space of said first shell, and said embedding part of said second shell is embedded into said first shell such that said second shell is tightly combined with said first shell, and said integrated circuit is tightly combined with said second shell by said embedding element.

2. The micro security digital card as claimed in claim 1, wherein said first shell is made of plastic material.

3. The micro security digital card as claimed in claim 1, wherein said second shell is made of metal material.

4. The micro security digital card as claimed in claim 1, wherein said intermediate element is a thermoplastic plate, and said thermoplastic plate combines said second shell and said integrated circuit by heating and pressurizing.

5. The micro security digital card as claimed in claim 1, wherein said embedding parts of said second shell includes a first embedding part and a second embedding part.

6. The micro security digital card as claimed in claim 5, wherein said second embedding part is O-shaped.

7. The micro security digital card as claimed in claim 5, wherein said second embedding part is L-shaped.

8. The micro security digital card as claimed in claim 5, wherein said second embedding part is U-shaped.

9. The micro security digital card as claimed in claim 1, wherein each side of said first shell forms a bevel.

10. The micro security digital card as claimed in claim 1, wherein one outer side of said first shell is provided with a recess.
